(19) United States
(12) Patent Application Publication
(10) Pub. No.: US 2011/0266546 A1
(43) Pub. Date: Nov. 3, 2011

(54) DISPLAY DEVICE AND MANUFACTURING METHOD THEREOF

(75) Inventor: Chun-Gi You, Yongin-city (KR)

(73) Assignee: Samsung Mobile Display Co., Ltd., Yongin-city (KR)

(21) Appl. No.: 13/039,210

(22) Filed: Mar. 2, 2011

(30) Foreign Application Priority Data
May 3, 2010 (KR) 10-2010-0041391

(51) Int. Cl. H01L 29/04; H01L 33/08

(52) U.S. Cl. 257/59; 257/72; 438/34; 257/E33.005; 257/E29.003

(57) ABSTRACT

A display device and a manufacturing method thereof are disclosed. In one embodiment, the display device includes 1) a substrate having a pixel region, a transistor region, and a capacitor region and 2) a transistor formed in the transistor region, wherein the transistor comprises i) an active layer formed over the substrate, ii) a gate insulating layer formed on the active layer, iii) a gate electrode formed on the gate insulating layer, and iv) a first interlayer insulating layer covering the gate electrode and formed on the gate insulating layer, v) a second interlayer insulating layer formed on the first interlayer insulating layer and vi) a source electrode and a drain electrode electrically connected to the active layer. The display device further includes a capacitor formed in the capacitor region, wherein the capacitor comprises i) a lower electrode formed on the gate insulating layer and ii) an upper electrode formed on the first interlayer insulating layer, wherein the upper electrode is formed substantially directly above the lower electrode, and wherein the surface area of the lower electrode is less than the surface area of the upper electrode.

### CROSS-REFERENCE TO RELATED APPLICATION

This application claims priority to and the benefit of Korean Patent Application No. 10-2010-0041391, filed on May 3, 2010, in the Korean Intellectual Property Office, the entire content of which is incorporated herein by reference.

### BACKGROUND

1. Field

The described technology generally relates to a display device and a manufacturing method thereof, and particularly to a display device capable of omitting an impurity ion injecting process and a manufacturing method thereof.

2. Description of the Related Technology

Recently, flat panel displays have received considerable attention for commercial applications. Examples of such displays include a liquid crystal display (LCD), a plasma display panel (PDP), a field emission display (FED), an electrophoretic display (EPD), and organic light emitting display (OLED).

Flat panel displays may be categorized into either a passive matrix type or an active matrix type. The active matrix display generally includes sub-pixels which are arranged in the form of a matrix. This type of display is generally more frequently used than a passive matrix display because of its superior resolution and advantages in displaying a moving picture.

### SUMMARY

One inventive aspect is a display device which can prevent the degradation of a capacitor aperture ratio and simplify a manufacturing process.

Another aspect is a manufacturing method of the display device.

Another aspect is a display device, including a substrate having a pixel region, a transistor region, and a capacitor region. The display device includes a transistor positioned in the transistor region of the substrate and including an active layer positioned on the substrate by interposing a gate insulating layer, a gate electrode, and a first interlayer insulating layer and a second interlayer insulating layer that are positioned between the gate electrode, a source electrode, and a drain electrode.

The display device includes a capacitor positioned in the capacitor region of the substrate and including a lower electrode positioned on the substrate and an upper electrode overlapped with the lower electrode by interposing the first interlayer insulating layer. The area of the lower electrode is less than an area of the upper electrode.

The first interlayer insulating layer is made of an inorganic insulating material and the second interlayer insulating layer is made of an organic insulating material. The lower electrode is made of the same material as that of the gate electrode and the upper electrode is made of the same material as those of the source electrode and the drain electrode.

The upper electrode penetrates the second interlayer insulating layer and is positioned on the first interlayer insulating layer. The source electrode and the drain electrode penetrate the gate insulating layer, the first interlayer insulating layer, and the second interlayer insulating layer to be connected to the active layer.

The display device may further include a passivation layer formed on the second interlayer insulating layer on which the source electrode, the drain electrode, and the upper electrode are formed. The passivation layer is made of the same material as that of the second interlayer insulating layer. The display device may further include a semiconductor layer positioned in a region corresponding to the lower electrode between the substrate of the capacitor region and the gate insulating layer.

In one embodiment, an active layer is formed in a transistor region of a substrate having a pixel region, the transistor region and a capacitor region. A gate insulating layer is formed on overall surface of the substrate on which the active layer is formed. A gate electrode is formed on the gate insulating layer of the transistor region and a lower electrode is formed in the capacitor region.

The first interlayer insulating layer is formed on the substrate on which the gate electrode and the lower electrode are formed fourth and a second interlayer insulating layer is formed on the first interlayer insulating layer. A first etching process is performed to remove the second interlayer insulating layer of the transistor region and only a part of the second interlayer insulating layer of the capacitor region is etched to leave a part thereof.

A second etching process is performed to remove the first interlayer insulating layer of the transistor region to expose the active layer and the second interlayer insulating layer remained in the capacitor region is removed to expose the first interlayer insulating layer of the transistor region.

An upper electrode is formed on the first interlayer insulating layer exposed in the transistor region simultaneously with forming a source electrode and a drain electrode that are electrically connected to the exposed active layer. An area of the lower electrode is less than an area of the upper electrode.

The first interlayer insulating layer is made of an inorganic insulating material and the second interlayer insulating layer is made of an organic material. The thickness of the remaining second interlayer insulating layer may be equal to or greater than 500 Å and equal to or less than 1000 Å during the first etching process. The thickness of the second interlayer insulating layer may be greater than a thickness of the first interlayer insulating layer.

The source electrode and the drain electrode penetrate the gate insulating layer, the first interlayer insulating layer, and the second interlayer insulating layer to be electrically connected to the active layer, and the upper electrode penetrates the second interlayer insulating layer to be formed on the first interlayer insulating layer.

The method may further include: forming a passivation layer on the substrate on which the source electrode, the drain electrode, and the upper electrode are formed; and forming an electrode penetrating the passivation layer and being electrically connected to the source electrode. The passivation layer may be made of the same material as that of the second interlayer insulating layer. The method may further include forming a semiconductor layer in the capacitor region of the substrate during the formation of the active layer in the transistor region.

In one embodiment, a transistor is formed in a transistor region of a substrate having a pixel region, the transistor region, and a capacitor region and a capacitor including a lower electrode and an upper electrode is formed in the capacitor region by interposing an interlayer insulating layer. Passivation layers are formed on the transistor and the capacitor.

An electrode that is electrically connected to the transistor is formed on the passivation layer. The area of the lower electrode is less than an area of the upper electrode.

In order to form the transistor, an active layer is formed in the transistor region of the substrate. A gate insulating layer is formed on the active layer and a gate electrode is formed on the gate insulating layer. An inorganic insulating material is formed on the gate electrode and an organic insulating material is formed on the inorganic insulating material. A source electrode and a drain electrode, which penetrate the inorganic insulating material and the organic insulating material and which are electrically connected to the active layer, are formed.

In order to form the capacitor, a gate insulating layer is formed in the capacitor region of the substrate. The lower electrode is formed on the gate insulating layer and an inorganic insulating material is formed on the lower electrode. An organic insulating material having a step is formed on the inorganic insulating material and the organic insulating material having the step of a region that corresponds to the lower electrode. The upper electrode is formed on the inorganic insulating material.

The thickness of the organic insulating material of the region that corresponds to the lower electrode may be equal to or greater than 500 Å and may be equal to or less than 1000 Å. The passivation layer may be made of the same material as the organic insulating material. The method may further include forming a semiconductor layer in the capacitor region of the substrate, performed before forming the gate insulating layer.

Another aspect is a display device comprising: a substrate having a pixel region, a transistor region, and a capacitor region; a transistor formed in the transistor region, wherein the transistor comprises i) an active layer formed over the substrate, ii) a gate insulating layer formed on the active layer, iii) a gate electrode formed on the gate insulating layer, and iv) a first interlayer insulating layer covering the gate electrode and formed on the gate insulating layer, v) a second interlayer insulating layer formed on the first interlayer insulating layer and vi) a source electrode and a drain electrode electrically connected to the active layer; and a capacitor formed in the capacitor region, wherein the capacitor comprises i) a lower electrode formed on the gate insulating layer and ii) an upper electrode formed on the first interlayer insulating layer, and wherein the upper electrode is formed substantially directly above the lower electrode; wherein the surface area of the lower electrode is less than the surface area of the upper electrode.

In the above device, the first interlayer insulating layer is formed at least partially of an inorganic insulating material and wherein the second interlayer insulating layer is formed at least partially of an organic insulating material. In the above device, the lower electrode is formed of the same material as that of the gate electrode and is covered by the first interlayer insulating layer, and wherein the upper electrode is made of the same material as those of the source electrode and the drain electrode.

In the above device, the upper electrode penetrates the second interlayer insulating layer so as to contact the first interlayer insulating layer. In the above device, the source electrode and the drain electrode penetrate i) the gate insulating layer and ii) the first and second interlayer insulating layers to be electrically connected to the active layer.

The above device further comprises a passivation layer formed on the second interlayer insulating layer and covering the source electrode, the drain electrode, and the upper electrode. In the above device, the passivation layer is formed of the same material as that of the second interlayer insulating layer.

The above device further comprises a semiconductor layer formed substantially directly below the lower electrode, wherein the semiconductor layer is covered by the gate insulating layer. In the above device, the second interlayer insulating layer is thicker than the first interlayer insulating layer.

Another aspect is a method of manufacturing a display device, the method comprising: forming an active layer in a transistor region of a substrate having a pixel region, the transistor region and a capacitor region; forming a gate insulating layer over the substrate so as to cover the active layer; forming i) a gate electrode on the gate insulating layer in the transistor region and ii) a lower electrode in the capacitor region; forming a first interlayer insulating layer on the gate insulating layer so as to cover the gate electrode and the lower electrode; forming a second interlayer insulating layer on the first interlayer insulating layer; removing first, second and third portions of the second interlayer insulating layer, wherein the first and second portions are formed substantially directly above the active layer, wherein the third portion is partially removed and formed substantially directly above the lower electrode; removing part of the first interlayer insulating layer and part of the gate insulating layer so as to expose the active layer; removing the remaining third portion of the second interlayer insulating layer to expose the first interlayer insulating layer in the capacitor region; and forming i) an upper electrode on the exposed portion of the first interlayer insulating layer in the capacitor region and ii) a source electrode and a drain electrode on the exposed portion of the active layer in the transistor region, wherein the surface area of the lower electrode is less than the surface area of the upper electrode.

In the above method, the first interlayer insulating layer has a raised portion formed substantially directly above the lower electrode so as to protrude toward the second interlayer insulating layer, wherein the second interlayer insulating layer has a fourth portion formed on the raised portion to be adjacent to the removed third portion of the second interlayer insulating layer in the capacitor region, and wherein the thickness of the fourth portion is in the range of about 500 Å to about 1000 Å.

In the above method, the second interlayer insulating layer is thicker than the first interlayer insulating layer. In the above method, the lower electrode is formed substantially simultaneously with the gate electrode and wherein the upper electrode is formed substantially simultaneously with the source electrode and the drain electrode.

Another aspect is a method of manufacturing a display device comprising: forming a transistor in a transistor region of a substrate having a pixel region, the transistor region, and a capacitor region; forming a capacitor including a lower electrode and an upper electrode in the capacitor region, wherein an interlayer insulating layer is interposed between the lower electrode and the upper electrode; forming a passivation layer on the transistor and the capacitor; and forming an electrode to be electrically connected to the transistor on the passivation layer, wherein the surface area of the lower electrode is less than the surface area of the upper electrode.

In the above method, the lower electrode is formed substantially directly below the upper electrode, and wherein the width of the lower electrode is less than or substantially equal to that of the upper electrode. In the above method, the upper electrode is substantially thicker than the lower electrode.

In the above method, the forming of the transistor comprises: forming an active layer in the transistor region; forming a gate insulating layer on the active layer; forming a gate electrode on the gate insulating layer to be substantially directly above the active layer; forming an inorganic insulating layer on the gate electrode; forming an organic insulating layer on the inorganic insulating layer; and forming a source electrode and a drain electrode that penetrate the inorganic insulating layer and the organic insulating layer, where the source and drain electrodes are electrically connected to the active layer.

In the above method, the forming of the capacitor comprises: forming a gate insulating layer in the capacitor region; forming the lower electrode on the gate insulating layer; forming an inorganic insulating layer on the lower electrode; forming an organic insulating layer, having a step, on the inorganic insulating layer; removing a first portion of the organic insulating layer, wherein the first portion of the organic insulating layer is formed substantially directly above the lower electrode; and forming the upper electrode in the removed first portion of the organic insulating layer so as to contact the inorganic insulating layer.

In the above method, the inorganic insulating layer has a raised portion formed substantially directly above the lower electrode so as to protrude toward the organic insulating layer, wherein the organic insulating layer has a second portion formed on the raised portion to be adjacent to the removed first portion of the organic insulating layer in the capacitor region, and wherein the thickness of the second portion is in the range of about 500 Å to about 1000 Å. The above method further comprises forming a semiconductor layer in the capacitor region, before forming the gate insulating layer, wherein the semiconductor layer is covered by the gate insulating layer.

### BRIEF DESCRIPTION OF THE DRAWINGS

FIG. 1 is a sectional view illustrating a display device according to an embodiment.

FIG. 2 is a sectional view illustrating a display device according to another embodiment.

FIGS. 3A to 3I are sectional views illustrating a manufacturing process of the display device of the embodiment of FIG. 1.

### DETAILED DESCRIPTION

A sub-pixel of an active matrix display generally includes at least one transistor and at least one capacitor which drive the sub-pixel. Each of the transistor and capacitor includes an active layer and a lower electrode. In this case, since the active layer of the transistor and the lower electrode of the capacitor are generally made of semiconductor material, the impurity ion injecting process is performed. The impurity ion injecting process is independently performed to the transistor and the capacitor.

Thus, in addition to the impurity ion injecting process on the transistor, an additional mask and processing is needed to form the lower electrode of the capacitor. This increases manufacturing costs and reduces yield.

In the following detailed description, only certain exemplary embodiments have been shown and described, simply by way of illustration. As those skilled in the art would realize, the described embodiments may be modified in various different ways. Accordingly, the drawings and description are to be regarded as illustrative in nature and not restrictive. In addition, when an element is referred to as being “on” another element, it can be directly on the another element or be indirectly on the another element with one or more intervening elements interposed therebetween. Also, when an element is referred to as being “connected to” another element, it can be directly connected to the another element or be indirectly connected to the another element with one or more intervening elements interposed therebetween. Hereinafter, like reference numerals refer to like elements.

Hereinafter, a display device and a manufacturing method thereof according to an embodiment will be described in detail with reference to the accompanying drawings. Here, i) shapes, sizes, ratios, angles, and numbers that are illustrated in the accompanying drawings may be slightly changed. ii) Since the drawings are depicted from observer's eyes, the directions and positions illustrating the drawings may be variously changed according to the observer's position. iii) Different reference numerals may be assigned to the same part. iv) In the case where the terms ‘comprising’, ‘having’, and ‘including’ are used, another term may be added when the term ‘only’ is not used. v) A singularity may be interpreted by plurality. vi) Although shapes, comparison of size, and positional relationship are not explained by ‘about’, ‘substantially’, etc., the shapes, comparison of size, and positional relationship are interpreted to include usual error range. vii) Although the terms ‘after ˜’, ‘before ˜’, ‘then’, ‘and’, ‘here’, ‘next’, ‘at this time’, and ‘in this case’ are used, the terms do not mean the limitation of time position. viii) The terms ‘first’, ‘second’, and ‘third’, etc., are used for conventional distinguish selectively, exchangeably, or repeatedly, but are not interpreted by limit meaning. ix) In the case where positional relationship between two parts such as ‘on ˜’, ‘above ˜’, ‘under ˜’, and ‘beside ˜’ is described, one or more other part may be positioned between the two parts when the term ‘directly’ is not used. x) When parts are connected by the term ‘or’, the connection is interpreted to include not only the parts but also the combinations of the parts. When the parts are connected to each other by the term ‘one of ˜, or ˜’, the connection means only the parts.

### Display Device

FIG. 1 is a sectional view illustrating a display device according to an embodiment.

The embodiment illustrated in FIG. 1 shows an example of a display device implemented by twisted nematic (TN) and vertically aligned (VA) mode. FIG. 1, for the illustrative purpose, shows a substrate in which one sub-pixel including a transistor and a capacitor. However, the disclosed embodiments may be applied to all kinds of display devices including OLED.

Referring to FIG. 1, the display device includes a substrate 10 having a pixel region P, a transistor region T, and a capacitor region C, and a transistor TFT and a capacitor Cst that are positioned on the substrate 10.

The transistor TFT includes an active layer 14 positioned on the substrate 10, a gate insulating layer 16 positioned on the active layer 14, a gate electrode 19, an interlayer insulating layer 23, a source electrode 26, and a drain electrode 27.

The active layer 14 forms a conductive channel between the source electrode 26 and the drain electrode 27 and supplies the voltage that is provided to the source electrode 26 when a gate signal is supplied to the gate electrode 19 to the drain electrode 27. The active layer 14 includes i) a source region 15a that is electrically connected to the source electrode 26 and is doped with impurity and ii) a drain region 15b that is electrically connected to the drain electrode 27 and is doped with impurity. A channel region is formed between the source region 15a and the drain region 15b. In one embodiment, the active layer 14 includes amorphous silicon or polysilicon and is positioned over the substrate 10.

In one embodiment, the gate electrode 19 is positioned on the gate insulating layer 16 and is formed substantially directly above the channel region of the active layer 14. The gate electrode 19 is electrically connected to the gate line (not shown), and receives a gate signal from the gate line. In one embodiment, the gate electrode 19 is made of the same material as that of a lower electrode 20 of the capacitor Cst and formed substantially on the same plane as that of the lower electrode 20. In this embodiment, the distance between the gate electrode 19 and the substrate 10 is substantially the same as the distance between the lower electrode 20 and the substrate 10 as shown in FIG. 1.

The source electrode 26 and the drain electrode 27 are positioned on an interlayer insulating layer 23 formed on the front surface of the substrate 10 on which the gate electrode 19 is formed. The interlayer insulating layer 23 has a stacked structure of a first interlayer insulating layer 22 and a second interlayer insulating layer 24. In one embodiment, the first interlayer insulating layer 22 is formed at least partially of inorganic material and the second interlayer insulating layer 24 is formed at least partially of an organic material.

In this embodiment, the thickness of the second interlayer insulating layer 24 may be greater than the thickness of the first interlayer insulating layer 22. The inorganic material forming the first interlayer insulating layer 22 may be any inorganic material including silicon nitride, silicon oxide, or silicon oxynitride. The organic material forming the second interlayer insulating layer 24 may be any commercially available organic insulating material.

Since the above embodiment can prevent a step within the sub-pixel by additionally including the second organic interlayer insulating layer 24 in addition to the first interlayer insulating layer 22, it is possible to omit a passivation layer 30.

The source electrode 26 is electrically connected to the source region 15a of the active layer 14 that is exposed through an opening of the interlayer insulating layer 23. The drain electrode 27 is electrically connected to the drain region 15b of the active layer 14 that is exposed through the other opening of the interlayer insulating layer 23. The drain electrode 27 or the source electrode 26 is electrically connected to an electrode 32 that is formed in the pixel region P.

In one embodiment where the above display device is an LCD, the electrode 32 is used as a pixel electrode and applies a voltage to a liquid crystal (not shown). In another embodiment where the display device is an OLED, the electrode 32 is used as an anode or a cathode.

The capacitor Cst is formed by substantially overlapping the lower electrode 20 and an upper electrode 28 and by interposing the first interlayer insulating layer 22. In this embodiment, the first interlayer insulating layer 22 that is formed at least partially of an inorganic insulating material is used as dielectrics.

The lower electrode 20 is positioned on the gate insulating layer 16. In one embodiment, the upper electrode 28 of the capacitor Cst is made of the same material as those of the source electrode 26 and the drain electrode 27 and is formed on the first interlayer insulating layer 22 by piercing the second interlayer insulating layer 24.

In one embodiment, an area of the lower electrode 20 of the capacitor Cst maintains a predetermined value, but an area of the upper electrode 28 may vary according to the size of an opening piercing the second interlayer insulating layer 24. In one embodiment, the area of the lower electrode 20 is smaller than the area of the upper electrode 28 so that capacitance of the capacitor Cst can be maintained substantially constant or can be easily controlled, and that desired property and dispersion of the capacitor can be obtained. The area may be a surface area of the electrodes 20 and 28 of the capacitor Cst. Further, the area may be that of a cross-section of the electrodes 20 and 28 seen from the top or bottom of the display device. The upper electrode 28 may be thicker or substantially thicker (e.g., at least 2-3 times) than the lower electrode 20. Moreover, the dimension of the upper electrode 28 may be substantially greater than that of the lower electrode 20.

The above display device may further include a passivation layer 30 for preventing a buffer layer 12 that is formed on the substrate 10, the transistor TFT, and the capacitor Cst. The passivation layer 30 may be made of the same material as that of the second interlayer insulating layer 24 and may be made of a material different from that of the first interlayer insulating layer 22.

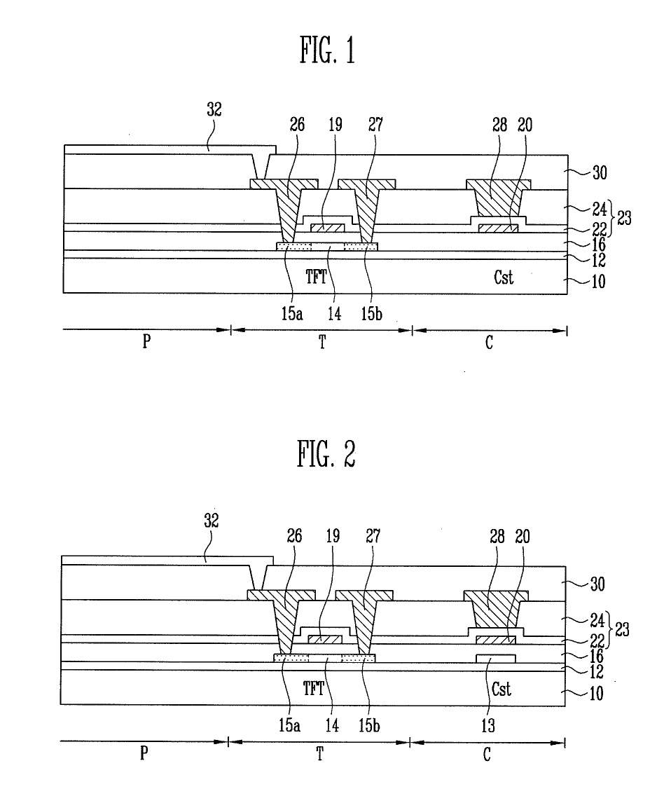

The FIG. 2 display device may further include a semiconductor layer 13 formed in the capacitor region C on the substrate 10. In one embodiment, the semiconductor layer 13 is formed on the buffer layer 12 and formed substantially directly below the lower electrode 20. In one embodiment, the electrostatic capacity of the capacitor Cst is defined by i) the semiconductor layer 13 and the lower electrode 20 and ii) the lower electrode 20 and the upper electrode 28. In this embodiment, the gate insulating layer 16 and the first interlayer insulating layer 22 are used as dielectrics, respectively.

Since the impurity ions are not injected into the semiconductor layer 13 (will be described later), an additional mask and an ion injecting process are not necessary. Meanwhile, since elements assigned with the same reference numerals are identical to those of FIG. 1, the description will be omitted.

Manufacturing Method of Display Device

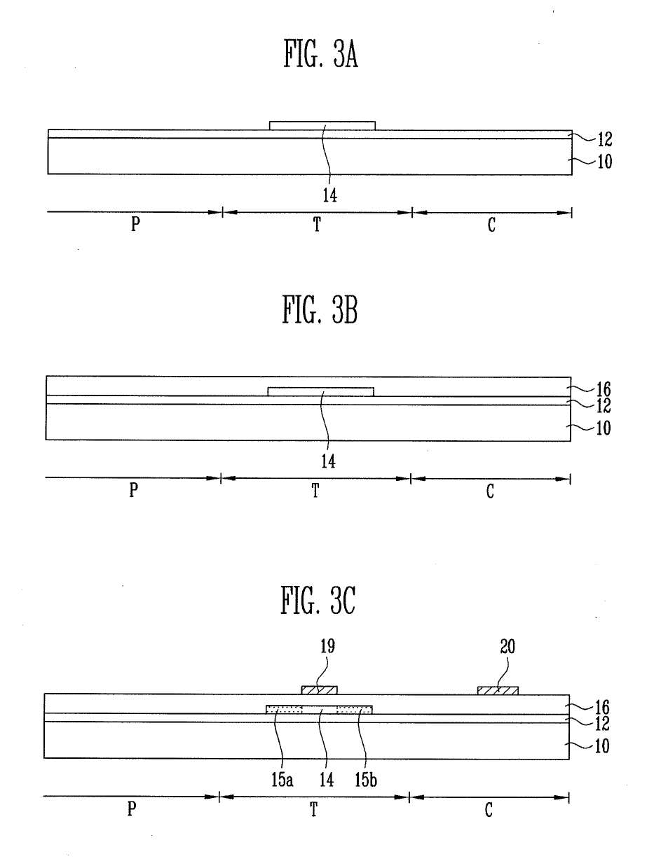

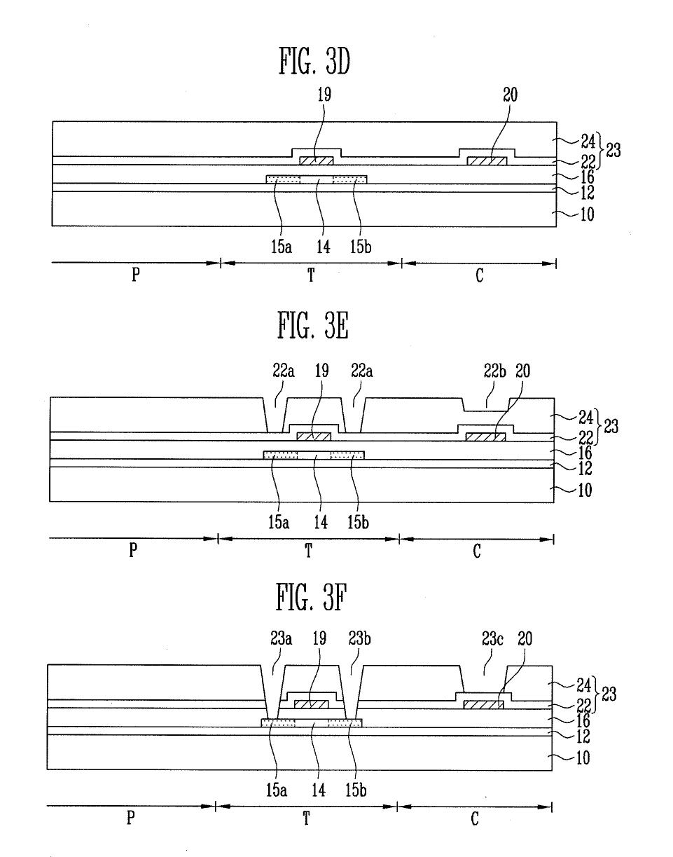

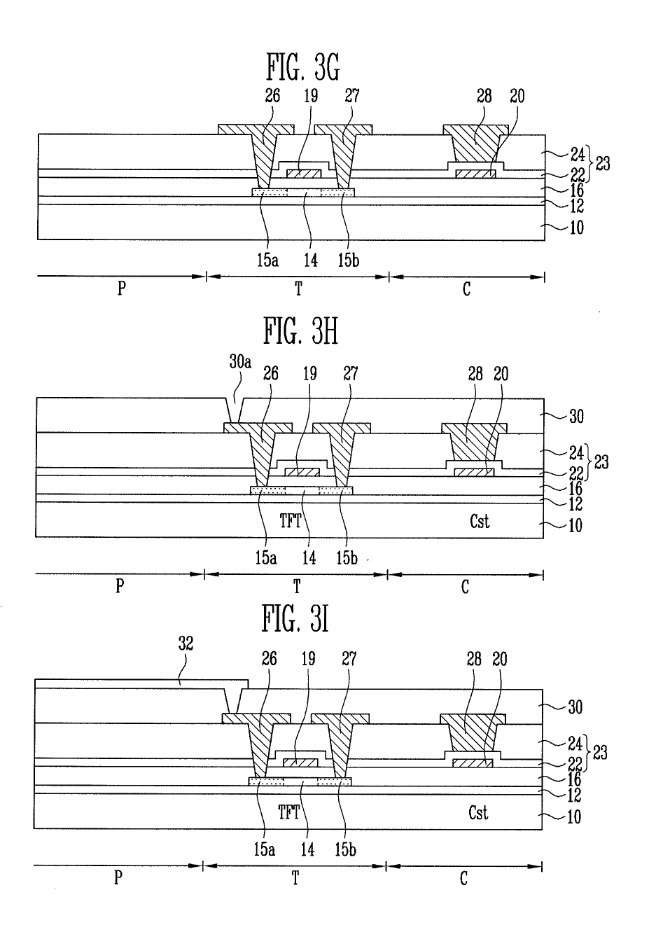

Hereinafter, a manufacturing method of the display device according to an embodiment will be described with reference to FIGS. 3A to 3I. FIGS. 3A to 3I are sectional views illustrating a manufacturing process of the display device of the embodiment of FIG. 1.

Referring to FIG. 3A, the active layer 14 is formed in the transistor region T of the substrate 10 having the transistor region T, the capacitor region C, and the pixel region P. Before the active layer 14 is formed, an etching preventing buffer layer 12 may be further formed on the front surface of the substrate 10. In one embodiment, the active layer 14 is formed by forming amorphous silicon or poly-silicon on the whole front surface of the substrate 10 and by patterning the same in photographing and etching process using a first mask. Depending one the embodiment, a crystallizing process may be further performed.

Referring to FIG. 3B, the gate insulating layer 16 is formed on the whole substrate 10 including the active layer 14. The gate insulating layer 16 may be formed at least partially of silicon oxide, silicon nitride, and silicon oxynitride.

Referring to FIG. 3C, the gate electrode 19 is formed in the transistor region T of the substrate 10 and the lower electrode 20 is formed in the capacitor region C. In one embodiment, the gate electrode 19 and the lower electrode 20 are formed by coating a first conductive material (not shown) on the gate insulating layer 16 and by patterning the coated first conductive material by photographing and etching process using a second mask.

The gate electrode 19 and the lower electrode 20 may be formed at least partially of metal such as tungsten (W), titanium (Ti), molybdenum (Mo), silver (Ag), tantalum (Ta), aluminum (Al), copper (Cu), gold (Au), chrome (Cr), and niobium (Nb) or an alloy thereof. In one embodiment, the gate electrode 19 is formed on the gate insulating layer 16 and formed substantially directly above the channel region of the active layer 14.

Next, the impurity ions are injected into both edges of the active layer 14 by using the gate electrode 19 as a mask so that the source region 15a and the drain region 15b are formed.

Referring to FIG. 3D, the interlayer insulating layer 23 is formed on the gate insulating layer 16. The interlayer insulating layer 23 is formed by sequentially forming the first interlayer insulating layer 22 and the second interlayer insulating layer 24 on the gate insulating layer 16. The thickness of the second interlayer insulating layer 24 may be greater than that of the first interlayer insulating layer 22.

As described above, the first interlayer insulating layer 22 may be formed at least partially of an inorganic insulating material and the second interlayer insulating layer 24 may be formed at least partially of an organic insulating material.

Referring to FIG. 3E, first openings 22a for exposing the first interlayer insulating layer 22 of the transistor region T and a second opening 22b in which only part of the second interlayer insulating layer 24 of the capacitor region C is removed are formed. The openings 22a and 22b may be formed by patterning the second interlayer insulating layer 24 in the photographing process using a third mask (for example, a half tone mask) and a first etching process.

In one embodiment, the second interlayer insulating layer 24 of the capacitor C has a step due to the second opening 22b.

The first opening 22a may be positioned substantially directly above the source region 15a and the drain region 15b. Further, the second opening 22b may be positioned substantially directly above the lower electrode 20. When a half tone mask is used as a third mask, the first interlayer insulating layer 22 of the transistor region T is exposed but the first interlayer insulating layer 22 of the capacitor region C is not exposed.

In one embodiment, the thickness of the remaining second interlayer insulating layer 24 is in the range of about 500 Å to about 1000 Å. The above range may be advantageous in terms of avoiding i) the exposed area of the first interlayer insulating layer 22 (during the etching process) being easily changed and ii) decrease in electrostatic capacity. However, it is possible that the above thickness is less than about 500 Å or greater than about 1000 Å depending on the embodiment.

Referring to FIG. 3F, a first contact hole 23a and a second contact hole 23b are formed by removing the exposed first interlayer insulating layer 22 in a second etching process. Further, substantially simultaneously, the second interlayer insulating layer 24 remaining in the capacitor region C is removed to form a third contact hole 23c.

The first contact hole 23a exposes the source region 15a of the active layer 14 and the second contact hole 23b exposes the drain region 15b of the active layer 14. The third contact hole 23c exposes the first interlayer insulating layer 22 corresponding to the lower electrode 20 of the capacitor region C.

In at least one embodiment, since the interlayer insulating layer 23 is removed by performing the etching process twice during the formation of the contact holes, the dimension of the layer exposed by the contact holes can be precisely controlled. Further, it is possible to easily control the area of the third contact hole 23c on which the upper electrode will be formed to prevent the area of the third contact hole 23c from being excessively increased. Thus, it is possible to prevent the aperture ratio from being inferior.

Moreover, at least one embodiment can prevent the steps of the layers within the sub-pixel using the accumulated structure of the second interlayer insulating layer 24 including the organic insulating material as the interlayer insulating layer 23.

Referring to FIG. 3G, the source electrode 26, the drain electrode 27, and the upper electrode 28 for filling the first contact hole 23a, the second contact hole 23b, and the third contact hole 23c, respectively, are formed. In one embodiment, the source electrode 26, the drain electrode 27, and the upper electrode 28 are formed by forming a second conductive material (not shown) on the interlayer insulating layer 23 and after that by patterning the second conductive material in the photographing process and the etching process using a fourth mask. When the area of the upper electrode 28 is greater than the area of the lower electrode 20, it is possible to maintain the capacity of the capacitor at a predetermined capacity or to adjust the capacity of the capacitor, and to obtain desired property of the capacitor and desired dispersion. In this case, the upper electrode 28 penetrates the second interlayer insulating layer 24 and is positioned on the first interlayer insulating layer 22 to overlap with the lower electrode 20.

The source electrode 26, the drain electrode 27, and the upper electrode 28 may be formed at least partially of metal or metal alloy such as molybdenum (Mo) or molybdenum tungsten (MoW).

Referring to FIG. 3H, the passivation layer 30 is formed on the interlayer insulating layer 23, the source electrode 26 and the drain electrode 27. Further, a fourth contact hole 30a is formed by the photographing and etching process using a fifth mask. The source electrode 26 is exposed through the fourth contact hole 30a.

The passivation layer 30 may be formed of the same inorganic insulating material as that of the first interlayer insulating layer 22 with the use of PECVD, spin coating, and spinless coating. Alternatively, the passivation layer 30 may be formed of the same organic insulating material as that of the second interlayer insulating layer 24. The passivation layer 30 may be omitted or formed thin according to the thickness of the second interlayer insulating layer 24.

In one embodiment, as shown in FIG. 3I, after forming the third conductive material, the electrode 32 is formed in the pixel region P by the photographing and etching process using a sixth mask. The electrode 32 is electrically connected to the source electrode 26 or the drain electrode 27.

According to at least one embodiment, since i) the gate electrode and the source/drain electrodes of the transistor and ii) the electrodes of the capacitor are manufactured substantially in the same process, an additional impurity ion injecting process for the capacitor electrodes can be omitted. Thus, manufacturing costs are reduced and overall process is simplified.

In addition, at least one of the disclosed embodiments uses the accumulated structure of an inorganic insulating layer and an organic insulating layer as the interlayer layer, an area where an upper electrode of the capacitor will be formed can be easily controlled during the etching process using a half tone mask.

Moreover, since at least one of the disclosed embodiments prevents the layers within the sub-pixel from having steps using the accumulated interlayer insulating layers and prevents the area of the upper electrode of the capacitor from being excessively increased, it is possible to prevent the deterioration of an aperture ratio.

In addition, at least some disclosed embodiments make the area of the lower electrode of the capacitor be less than the area of the upper electrode so that the capacity of the capacitor can be maintained at a predetermined value and easily controlled, and desired characteristics of the capacitor can be obtained.

The disclosed embodiments are not considered to be limiting and may cover various modifications and equivalent arrangements included within the spirit and scope of the appended claims.

What is claimed is:

1. A display device comprising:
a substrate having a pixel region, a transistor region, and a capacitor region;
a transistor formed in the transistor region, wherein the transistor comprises i) an active layer formed over the substrate, ii) a gate insulating layer formed on the active layer, iii) a gate electrode formed on the gate insulating layer, and iv) a first interlayer insulating layer covering the gate electrode and formed on the gate insulating layer, v) a second interlayer insulating layer formed on the first interlayer insulating layer and vi) a source electrode and a drain electrode electrically connected to the active layer; and
a capacitor formed in the capacitor region, wherein the capacitor comprises i) a lower electrode formed on the gate insulating layer and ii) an upper electrode formed on the first interlayer insulating layer, and wherein the upper electrode is formed substantially directly above the lower electrode,
wherein the surface area of the lower electrode is less than the surface area of the upper electrode.

2. The display device as claimed in claim 1, wherein the first interlayer insulating layer is formed at least partially of an inorganic insulating material and wherein the second interlayer insulating layer is formed at least partially of an organic insulating material.

3. The display device as claimed in claim 1, wherein the lower electrode is formed of the same material as that of the gate electrode and is covered by the first interlayer insulating layer, and wherein the upper electrode is made of the same material as those of the source electrode and the drain electrode.

4. The display device as claimed in claim 1, wherein the upper electrode penetrates the second interlayer insulating layer so as to contact the first interlayer insulating layer.

5. The display device as claimed in claim 1, wherein the source electrode and the drain electrode penetrate i) the gate insulating layer and ii) the first and second interlayer insulating layers to be electrically connected to the active layer.

6. The display device as claimed in claim 1, further comprising a passivation layer formed on the second interlayer insulating layer and covering the source electrode, the drain electrode, and the upper electrode.

7. The display device as claimed in claim 6, wherein the passivation layer is formed of the same material as that of the second interlayer insulating layer.

8. The display device as claimed in claim 1, further comprising a semiconductor layer formed substantially directly below the lower electrode, wherein the semiconductor layer is covered by the gate insulating layer.

9. The display device as claimed in claim 1, wherein the second interlayer insulating layer is thicker than the first interlayer insulating layer.

10. A method of manufacturing a display device, the method comprising:
forming an active layer in a transistor region of a substrate having a pixel region, the transistor region and a capacitor region;
forming a gate insulating layer over the substrate so as to cover the active layer;
forming i) a gate electrode on the gate insulating layer in the transistor region and ii) a lower electrode in the capacitor region;
forming a first interlayer insulating layer on the gate insulating layer so as to cover the gate electrode and the lower electrode;
forming a second interlayer insulating layer on the first interlayer insulating layer;
removing first, second and third portions of the second interlayer insulating layer, wherein the first and second portions are formed substantially directly above the active layer, wherein the third portion is partially removed and formed substantially directly above the lower electrode;
removing part of the first interlayer insulating layer and part of the gate insulating layer so as to expose the active layer;
removing the remaining third portion of the second interlayer insulating layer to expose the first interlayer insulating layer in the capacitor region; and
forming i) an upper electrode on the exposed portion of the first interlayer insulating layer in the capacitor region and ii) a source electrode and a drain electrode on the exposed portion of the active layer in the transistor region,
wherein the surface area of the lower electrode is less than the surface area of the upper electrode.

11. The method as claimed in claim 10, wherein the first interlayer insulating layer has a raised portion formed substantially directly above the lower electrode so as to protrude toward the second interlayer insulating layer, wherein the second interlayer insulating layer has a fourth portion formed on the raised portion to be adjacent to the removed third portion of the second interlayer insulating layer in the capacitor region, and wherein the thickness of the fourth portion is in the range of about 500 Å to about 1000 Å.

12. The method as claimed in claim 10, wherein the second interlayer insulating layer is thicker than the first interlayer insulating layer.

13. The method as claimed in claim 10, wherein the lower electrode is formed substantially simultaneously with the gate electrode and wherein the upper electrode is formed substantially simultaneously with the source electrode and the drain electrode.

14. A method of manufacturing a display device comprising:
forming a transistor in a transistor region of a substrate having a pixel region, the transistor region, and a capacitor region;
forming a capacitor including a lower electrode and an upper electrode in the capacitor region, wherein an interlayer insulating layer is interposed between the lower electrode and the upper electrode;
forming a passivation layer on the transistor and the capacitor; and
forming an electrode to be electrically connected to the transistor on the passivation layer,
wherein the surface area of the lower electrode is less than the surface area of the upper electrode.

15. The method as claimed in claim 14, wherein the lower electrode is formed substantially directly below the upper electrode, and wherein the width of the lower electrode is less than or substantially equal to that of the upper electrode.

16. The method as claimed in claim 14, wherein the upper electrode is substantially thicker than the lower electrode.

17. The method as claimed in claim 14, wherein the forming of the transistor comprises:
forming an active layer in the transistor region;
forming a gate insulating layer on the active layer;
forming a gate electrode on the gate insulating layer to be substantially directly above the active layer;
forming an inorganic insulating layer on the gate electrode;
forming an organic insulating layer on the inorganic insulating layer; and
forming a source electrode and a drain electrode that penetrate the inorganic insulating layer and the organic insulating layer, where the source and drain electrodes are electrically connected to the active layer.

18. The method as claimed in claim 14, wherein the forming of the capacitor comprises:
forming a gate insulating layer in the capacitor region;
forming the lower electrode on the gate insulating layer;
forming an inorganic insulating layer on the lower electrode;
forming an organic insulating layer, having a step, on the inorganic insulating layer;
removing a first portion of the organic insulating layer, wherein the first portion of the organic insulating layer is formed substantially directly above the lower electrode; and
forming the upper electrode in the removed first portion of the organic insulating layer so as to contact the inorganic insulating layer.

19. The method as claimed in claim 18, wherein the inorganic insulating layer has a raised portion formed substantially directly above the lower electrode so as to protrude toward the organic insulating layer, wherein the organic insulating layer has a second portion formed on the raised portion to be adjacent to the removed first portion of the organic insulating layer in the capacitor region, and wherein the thickness of the second portion is in the range of about 500 Å to about 1000 Å.

20. The method as claimed in claim 18, further comprising forming a semiconductor layer in the capacitor region, before forming the gate insulating layer, wherein the semiconductor layer is covered by the gate insulating layer.
